(19) United States
(12) Patent Application Publication
(10) Pub. No.: US 2009/0179550 A1
(43) Pub. Date: Jul. 16, 2009

(54) ORGANIC LIGHT EMITTING DISPLAY DEVICE HAVING PROTECTING LAYERS AND METHOD OF MANUFACTURING THE SAME

(75) Inventors: Won-Hoe KOO, Suwon-si (KR); Hoon KIM, Hwaseong-si (KR); Jung-Mi CHOI, Yongin-si (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 12/042,046

(22) Filed: Mar. 4, 2008

(30) Foreign Application Priority Data
Jan. 15, 2008 (KR) 10-2008-0004282

(51) Int. Cl. H01L 27/32; H01J 9/02

(52) U.S. Cl. 313/504; 445/24

(57) ABSTRACT

An organic light emitting display device includes: a substrate; an organic light emitting pixel unit formed on the substrate; a first protective layer formed on the organic light emitting pixel unit; a second protective layer formed on the first protective layer; and a third protective layer formed on the second protective layer and including a desiccant member.

### CROSS-REFERENCE TO RELATED APPLICATION

This application claims priority from Korean Patent Application No. 10-2008-0004282, filed on Jan. 15, 2008, the disclosure of which is incorporated herein by reference in its entirety.

### BACKGROUND

1. Field of Disclosure

The present disclosure relates to an organic light emitting display (OLED) device and, more particularly, to an OLED device having protective layers and to methods of manufacturing the same.

2. Description of Related Technology

One of the core technologies in the information and communication era is that of an image display device which can display a variety of information on a user-viewable screen. A general desire in the technology is to develop improved display devices that are thinner, lighter, more portable, and more reliable and provide higher performance than preceding generations of devices. Accordingly, various flat panel display devices, including OLED devices are being developed to reduce weight and volume, which are drawbacks of the older cathode ray tube (CRT) technologies.

In a classic OLED device, electrons and holes are respectively injected from an electron injection electrode (cathode) and a hole injection electrode (anode) into an emissive layer. The injected charge carriers combine with each other in the emissive layer and generate excitons, which emit light while transitioning from an excited energy state to a ground state.

When compared against competing flat panel technologies, OLED devices offer advantages such as low driving voltage, low power consumption, light weight, and natural color display. However they also have the problem of a comparatively shorter lifespan. One of the factors affecting the lifespan of the OLED device is oxidation due to permeation of oxygen and/or moisture into the device.

A conventional OLED device comprises an organic light emitting pixel unit having a thin film transistor (TFT), an electron injection electrode, an organic light emitting layer, and a hole injection electrode, where these are integrally formed on a substrate. A protective layer is provided for protecting the organic light emitting pixel unit from moisture, and a rigid cover substrate is bonded to the substrate.

The protective layer may be formed of silicon nitride or silicon oxide by a CVD (Chemical Vapor Deposition) or a sputtering method. The protective layer formed by the processes is so dense as to guarantee blocking moisture. However, when the protective layer is formed directly on the organic light emitting pixel unit by the processes, the organic light emitting pixel unit is likely to be damaged by thermal energy during the processes. Also, as the overall array of the organic light emitting pixel units has concave patterns, the protective layer formed to conform to the concave patterns possibly has many pin holes in itself, and moisture can permeate into the organic light emitting pixel units through the pin holes.

Alternatively, the protective layer may be formed thickly with a sealant material. This scheme has an advantage of easily forming the protective layer without damage, but does not guarantee moisture blocking. So, desiccant particles for absorbing moisture is commonly added to the sealant based protective layer. In this case, due to their variations in size, the desiccant particles can cause spot depressions in an underlying layer due to the pressure exerted from the top when the rigid substrate is bonded to the cover substrate. The spot depressions of the underlying layer can cause an electrical failure in which the electron injection electrode is shorted into contact with the hole injection electrode due to the pressurization of large sized desiccant particles, thus resulting in a pixel defect in which the organic light emitting pixel unit does not emit light.

### SUMMARY

The present disclosure provides an OLED device and a method of manufacturing the organic light emitting display device in a manner which prevents or reduces the likelihood of formation of spot depressions and deformations of electrodes due to presence of desiccant particles near such locations, while protecting the OLED device from moisture and oxygen outside.

In one exemplary embodiment, an organic light emitting display device comprises a substrate, an organic light emitting pixel unit formed on the substrate, a first protective layer formed on the organic light emitting pixel unit, a second protective layer formed on the first protective layer, and a third protective layer formed on the second protective layer and including a desiccant member.

At this case, the organic light emitting display device may further comprise a cover substrate compressively bonded to the third protective layer.

At this case, the first protective layer and the third protective layer may be formed of a sealant material that inhibits passage of moisture therethrough.

At this case, the first protective layer and the third protective layer may include an epoxy-base resin.

At this case, the second protective layer may be formed of silicon oxide or silicon nitride.

At this case, the thickness of the first protective layer may be larger than the maximum diameter of the desiccant member.

At this case, the thickness of the third protective layer may be larger than the maximum diameter of the desiccant member.

At this case, the desiccant member may be formed of talc or silica gel.

In another exemplary embodiment, a method of manufacturing an organic light emitting display device comprises forming an organic light emitting pixel unit on a substrate, forming a first protective layer on the organic light emitting pixel unit, forming a second protective layer on the first protective layer, and forming a third protective layer including a desiccant member on the second protective layer.

At this case, the method may further comprise compressively bonding a cover substrate on the third protective layer.

At this case, the first protective layer and the third protective layer may be formed by a dispensing or screen printing method.

At this case, the second protective layer may be formed by CVD or sputtering method.

In another exemplary embodiment, a method of manufacturing an organic light emitting display device comprises forming an organic light emitting pixel unit on a substrate, forming a first protective layer on the organic light emitting pixel unit, forming a second protective layer on the first protective layer, forming a third protective layer including a desiccant member on a cover substrate, and compressively bonding the substrate where the second protective layer is formed and the cover substrate where the third protective layer is formed on.

At this case, the first protective layer and the third protective layer may be formed by a dispensing or screen printing method.

At this case, the second protective layer may be formed by CVD or sputtering method.

In another exemplary embodiment, an organic light emitting display device comprises a substrate, an organic light emitting pixel unit formed on the substrate, a first protective means for preventing the organic light emitting pixel unit from being physically damaged, wherein the first protective means is formed on the organic light emitting pixel unit and having a planar surface, a second protective means for inhibiting passage of moisture and oxygen into the organic light emitting pixel unit, wherein the second protective means is formed on the first protective layer, and a third protective means for inhibiting passage of moisture and oxygen into the organic light emitting pixel unit, wherein the third protective means is formed on the second protective layer and includes a desiccant member.

At this case, the first protective means and the third protective means are formed of a sealant material.

At this case, the second protective means is formed of silicon oxide or silicon nitride.

### BRIEF DESCRIPTION OF THE DRAWINGS

The above and other features of the present disclosure will be described in reference to certain exemplary embodiments depicted in the attached drawings in which:

FIG. 1 is a plan view of an OLED device in accordance with an exemplary embodiment of the present disclosure;

FIG. 2 is a cross-sectional view taken along line I-I′ of FIG. 1;

FIG. 3a is a cross-sectional view illustrating a step of preparing a substrate where an organic light emitting pixel unit is formed.

FIG. 3b is a cross-sectional view illustrating a step of forming a first protective layer on the organic light emitting pixel unit.

FIG. 3c is a cross-sectional view illustrating a step of forming a second protective layer on the first protective layer.

FIG. 3d is a cross-sectional view illustrating a step of forming a third protective layer on the third protective layer.

### DETAILED DESCRIPTION

Reference will now be made in detail to exemplary embodiments of the present disclosure, depictions of which are illustrated in the accompanying drawings, wherein like reference numerals refer to generally alike elements throughout. The embodiments are described below in order to explain the present disclosure by referring to figures.

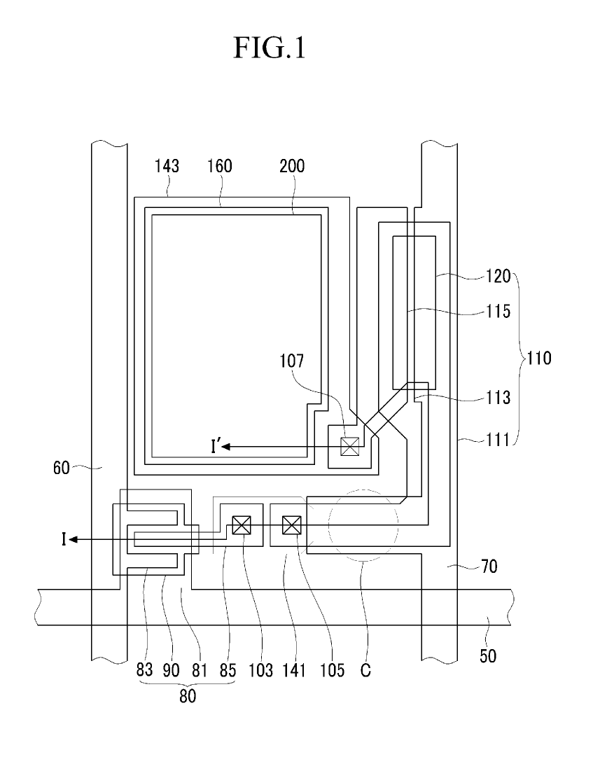

Hereinafter, exemplary embodiments of the present disclosure will now be described in detail with reference to FIGS. 1 to 3d. In the drawings, the thickness of layers and regions may be exaggerated for purpose of illustrative clarity.

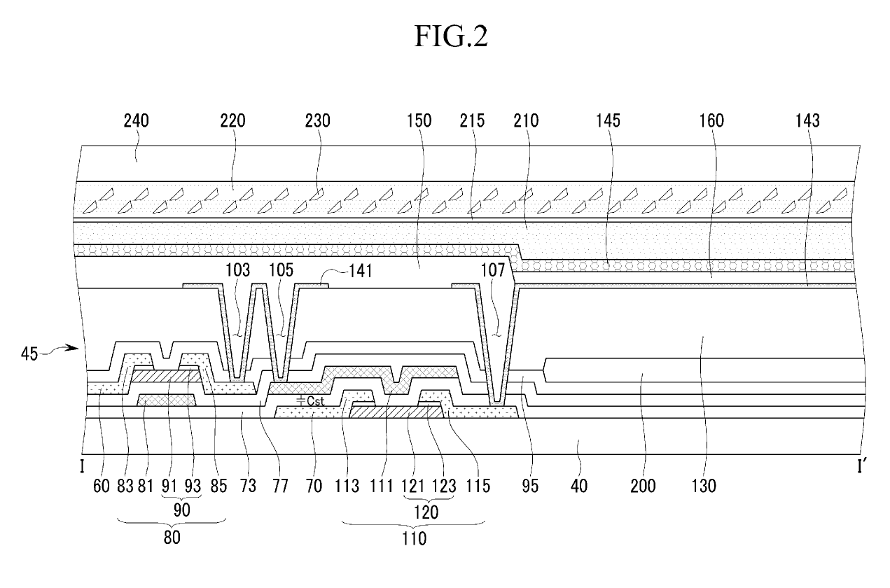

FIG. 1 is a plan view of an OLED device in accordance with the present disclosure, and FIG. 2 is a cross-sectional view taken along line I-I′ of FIG. 1.

Referring to FIGS. 1 and 2, the OLED device includes an organic light emitting pixel unit 45 (FIG. 2) formed on a transparent substrate 40 and including a gate line 50, a data line 60, a power line 70, a first thin film transistor (switching TFT) 80, a second thin film transistor (driving TFT) 110, a first electrode 143, an organic light emitting (OLE) layer 160, and a second electrode 145. As seen in FIG. 2, the second electrode 145 is disposed above the first electrode 143 (e.g., a light transmitting electrode 143 such as made of ITO) and the OLE layer 160 is sandwiched between them. The OLED device of the present disclosure also includes a first protective layer 210, a second protective layer 215, a third protective layer 220 and a cover substrate 240.

The substrate 40, on which a plurality of pixel units are arranged in a matrix form, may be formed of a transparent and electrically insulating material such as glass or plastic so that light transmits through the pixels.

The detailed structure of the organic light emitting pixel unit 45 will be explained below with reference to FIGS. 1 and 2.

The gate line 50 supplies a gate signal to the switching TFT 80, the data line 60 supplies a data signal to the switching TFT 80, and the power line 70 supplies a power signal to the driving TFT 110.

The switching TFT 80 is turned on when the gate line 50 is supplied with an activating gate signal so that the switching TFT 80 is rendered conductive to supply the data signal applied to the data line 60 to a storage capacitor Cst and a second gate electrode 111 of the driving TFT 110. For this purpose, the switching TFT 80 includes a first gate electrode 81 connected to the gate line 50, a first source electrode 83 connected to the data line 60, a first drain electrode 85 facing the first source electrode 83 and connected to a second gate electrode 111 of the driving TFT 110 and the storage capacitor Cst, and a first semiconductor pattern 90 defining a channel portion between the first source electrode 83 and the first drain electrode 85. The first semiconductor pattern 90 includes a first active layer 91 overlapping the first gate electrode 81 with a second gate insulating layer 77 disposed therebetween, and a first ohmic contact layer 93 formed on the first active layer 91 except for the channel portion to form an ohmic contact with the first source electrode 83 and the first drain electrode 85. The first active layer 91 may be formed of polysilicon or other forms of silicon (e.g., amorphous). In one embodiment, the first semiconductor layer 91 is formed of amorphous silicon which is advantageous to the on-off operation in view of desired characteristics of the switching TFT 80 which requires excellent discrete on-off characteristics.

The driving TFT 110 controls electric current supplied from the power line 70 to an organic light emitting cell, which will be described later, in response to the data signal applied to the second gate electrode 111 thereof, thus adjusting the light emitting amount of the organic light emitting cell. For this, the driving TFT 110 includes the second gate electrode 111 connected to the first drain electrode 85 through a connection electrode 141, a second source electrode 113 connected to the power line 70, a second drain electrode 115 facing the second source electrode 113 and connected to a first electrode 143 of the organic light emitting cell, and a second conductive pattern 120 forming a channel portion between the second source electrode 113 and the second drain electrode 115. The connection electrode 141 is formed of the same material as the first electrode 143 on a planarization layer 130. The connection electrode 141 connects the first drain electrode 85 of the switching TFT 80 exposed through a first contact hole 103 to the second gate electrode 111 of the driving TFT 110 exposed through a second contact hole 105. The first contact hole 103 penetrates a passivation layer 95 and the planarization layer 130 to expose the first drain electrode 85, and the second contact hole 105 penetrates the second gate insulating layer 77, the passivation layer 95 and the planarization layer 130 to expose the second gate electrode 111.

The second semiconductor pattern 120 includes a second active layer 121 overlapping the second gate electrode 111 with a first gate insulating layer 73 disposed therebetween, and a second ohmic contact layer 123 formed on the second active layer 121 except for the channel portion to form an ohmic contact with the second source electrode 113 and the second drain electrode 115. Such a second active layer 121 may be formed of amorphous silicon for example.

The second active layer 121 may alternatively be formed of polysilicon in view of the desired operating characteristics of the driving TFT 110 in which an electric current flows continuously during the frame-long light emission period of the organic light emitting cell.

The second gate electrode 111 of the driving TFT 110 overlaps the power line 70 with the second gate insulating layer 77, thus forming the storage capacitor Cst. Such a storage capacitor Cst helps to supply a constant current to the driving TFT 110 by maintaining the gate 111 of the driving TFT 110 with the charged voltage of the storage capacitor Cst until a data signal of the next frame is supplied so that the organic light emitting cell maintains the light emission, even though the switching TFT 80 is turned off in the interim.

The organic light emitting cell includes the first electrode 143 formed of a transparent conductive material on the planarization layer 130, an organic light emitting layer 160 including an emissive layer formed on the first electrode 143, and a second electrode 145 formed on the organic light emitting layer 160. Although not shown in detail, the organic light emitting layer 160 includes a hole injection layer, a hole transport layer, an optically emissive layer, an electron transport layer, and an electron injection layer, stacked in the recited order on the upper surface of the first electrode 143. The emissive layer may be formed in a triple layer structure in which emissive layers displaying red (R), green (G) and blue (B) colors are sequentially stacked, or in a double layer structure in which emissive layers having a complementary color relationship are stacked, or in a single layer structure composed of an emissive layer emitting a white color. Accordingly, the emissive layer provided in the organic light emitting layer 160 emits light in accordance with (e.g., in proportion to) the amount of the current applied to the second electrode 145 and the light of the organic light emitting layer 160 is transmitted toward a color filter 200 by way of the first electrode 143.

The first electrode 143 faces the second electrode 145 with the organic light emitting layer 160 disposed therebetween and formed every sub-pixel region. The first electrode 143 is formed independently in each sub-pixel region on the planarization layer 130. The first electrode 143 is coupled to the second drain electrode 115 of the driving TFT 110 exposed by a third contact hole 107 formed by etching the first and second gate insulating layers 73 and 77, the passivation layer 95, and the planarization layer 130. The first electrode 143 may be formed of a transparent conductive material such as indium tin oxide (ITO), indium zinc oxide (IZO), tin oxide (TO), or indium tin zinc oxide (ITZO).

A barrier layer 150 is formed on the upper surface of the connection electrode 141 connected to the planarization layer 130. The barrier layer 150 is formed of an organic material to serve as an insulating layer. The barrier layer 150 is patterned (e.g., opened up near hole 107) to expose the first electrode 143 such that the organic light emitting layer 160 is positioned on the upper surface of the first electrode 143.

The second electrode 145 may be formed of aluminum (Al), magnesium (Mg), silver (Ag), or calcium (Ca) having excellent electron transport capability and good reflection performance.

The color filter 200 is formed to overlap the organic light emitting layer 160 generating white light on the upper surface of the passivation layer 95. Accordingly, the color filter 200 displays red (R), green (G) and blue (B) colors using the white light produced from the organic light emitting layer 160. The R, G or B light is emitted to the outside through the transparent substrate 40.

Alternative structures can be substituted for that of the organic light emitting pixel unit 45 above explained. For example, the organic light emitting layer of each sub-pixel region includes only one of R, G, B colors to produce each R, G, B color. In this case, color filter 200 is not necessary component. Also, contrary to the structure in FIGS. 1 and 2, the first electrode 143 may be formed of reflective material, and the second electrode 145 may be formed of transparent material. In this case, the R, G or B light is emitted to the outside through the cover substrate 240, not the transparent substrate 40.

The protective layers 210, 215 and 220 are explained below in detail.

The first protective layer 210 is formed on the organic light emitting pixel unit 45. In one embodiment, the first protective layer 210 is formed of an epoxy-based conformal sealant in order to prevent moisture and oxygen from penetrating from the outside and to protect the organic light emitting pixel unit 45 from various physical damages. For example, the epoxy-based sealant may be formed of at least one member selected from the group consisting of bisphenol type epoxy resin, epoxidized butadiene resin, fluorine type epoxy resin, and novolac type epoxy resin.

The first protective layer 210 has a thickness greater than a step height of the second electrode 145 formed by the barrier layer 150 in order to reduce the step height, and the upper surface thereof is formed substantially planar (horizontally). The reason for this is to eliminate any space in which moisture or gas, which can cause damage to the organic light emitting layer 160, might be trapped due to respective layers to be stacked later on top of barrier layer 150 during mass production manufacture.

The second protective layer 215 is formed on the first protective layer 210. The second protective layer 215 is formed of silicon nitride or silicon oxide by a CVD or a sputtering method. The second protective layer 215 is so dense as to guarantee blocking moisture. Additionally, as first protective layer 210 functions as a buffer when the second protective layer 215 is formed, the organic light emitting pixel unit 45 below does not be damaged by the CVD or sputtering process for forming the second protective layer 215. Also, the second protective layer 215, formed along the substantially planar first protective layer 210, has a good uniformity without pin holes.

The third protective layer 220 is formed on the second protective layer 215. Like the first protective layer 210, the third protective layer 220 is formed of an epoxy-based sealant in order to prevent moisture or oxygen from penetrating from the outside. For example, the epoxy-based sealant may be formed of at least one member selected from the group consisting of bisphenol type epoxy resin, epoxidized butadiene resin, fluorine type epoxy resin, and novolac type epoxy resin.

However, unlike the first protective layer 210, the third protective layer 220 comprises desiccant members 230 (e.g., of average diameter of 5 microns) for absorbing moisture, distributed uniformly across the overall surface of the substrate 40. The desiccant members 230 functions as to remove moisture that manages to penetrate from the outside. For example, the desiccant members 230 may be formed of one or more moisture absorbing materials such as talc, which do not exhibit any substantial swelling property when exposed to water or organic solution. Moreover, silica gel may be included as the desiccant member 230. In this case, the desiccant members 230 should have a size (e.g., diameter) smaller than the thickness of the third protective layer 220 (or vise versa, the third protective layer 220 should have a thickness equal to or greater than the normally largest ones of the desiccant particles expected to be found in the first protective layer 210). For example, the largest normal ones of the desiccant members 230 may have a size (e.g., diameter) of less than about 5 μm, when the third protective layer 220 has a thickness of about 20 μm.

The first protective layer 210, the second protective layer 215 and the third protective layers 220 are structured to prevent an electrical failure from occurring in which the second electrode 145 is spot depressed into shorting contact with the first electrode 143, due to a depression force exerted by an overlying desiccant member 230 of large size (overlying in FIG. 2), of which description will be given in connection with the cover substrate 240 below.

Although it is exemplified above that the first protective layer 210 is formed of an epoxy-based conformal sealant, any protective means for preventing the organic light emitting pixel unit underlying from being physically damaged can be used for this purpose.

Also, although it is exemplified above that the second protective layer 215 is formed of a silicon oxide or silicon nitride, any protective means for inhibiting passage of moisture and oxygen into the organic light emitting pixel unit can be used for this purpose.

Also, although it is exemplified above that the third protective layer 220 is formed of an epoxy-based conformal sealant and desiccant members 230, any protective means for inhibiting passage of moisture and oxygen into the organic light emitting pixel unit can be used for this purpose.

The cover substrate 240 is positioned on the upper surface of the third protective layer 220 to protect the organic light emitting pixel unit 45 from an external impact. The cover substrate 240 helps to prevent moisture or oxygen from penetrating from the outside together with the first and third protective layers 210 and 220. Such a cover substrate 240 may be formed of a transparent insulating material such as glass or plastic, the same as the substrate 40. The material of the cover substrate 240 is not limited to glass or plastic, but may be formed of various other materials such as an organic, inorganic or metallic material.

The cover substrate 240 is compressively bonded to the third protective layer 220. The cover substrate 240 pressurizes the third protective layer 220 during the assembly process, thus potentially causing the depression of an underlying layer by large sized ones of the desiccant members 230 if the intervening first protective layer 210 were not present. However, at this time, the first protective layer 210 and the second protective layer 215 formed below the bottom of the third protective layer 220 acts to relieve the stress and strain of spot depressions caused by large ones of the desiccant members 230, thus preventing the undesirable spot depression of the second electrode 145 into shorting contact with the first electrode 143. Accordingly, it is possible to prevent an electrical failure caused by the contact between the second electrode 145 and the first electrode 143.

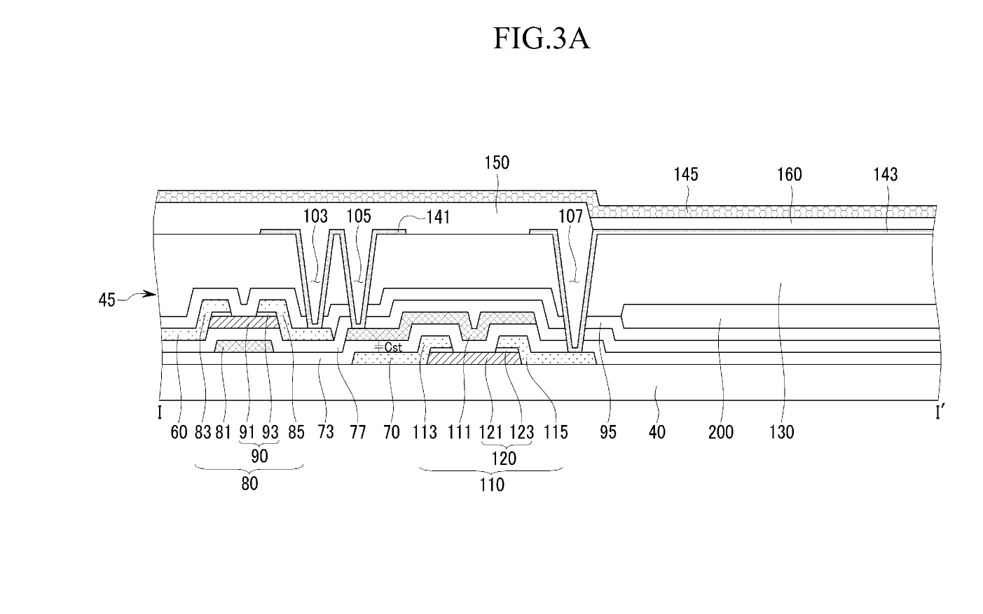

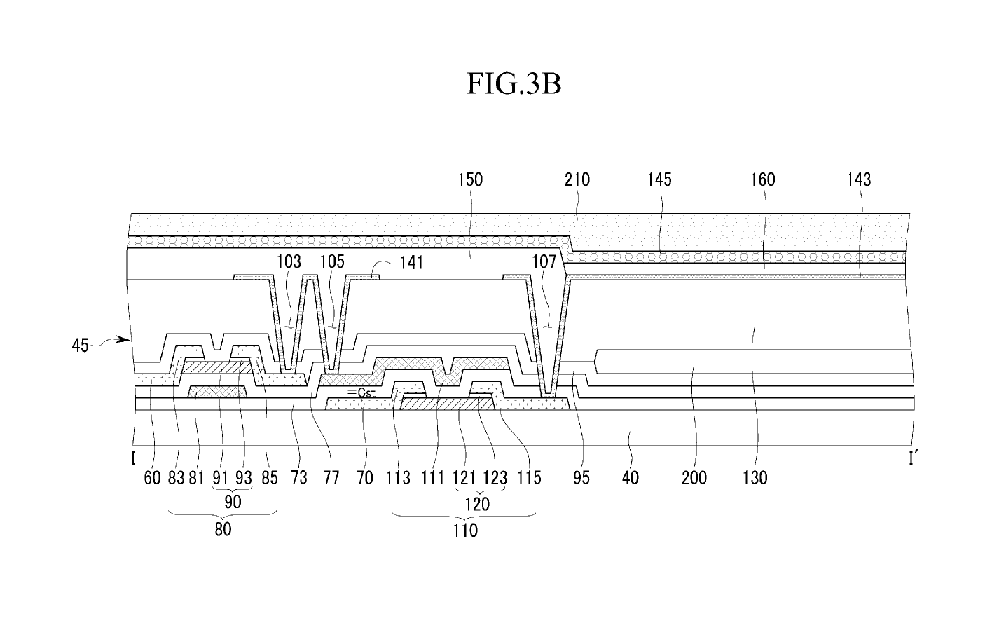

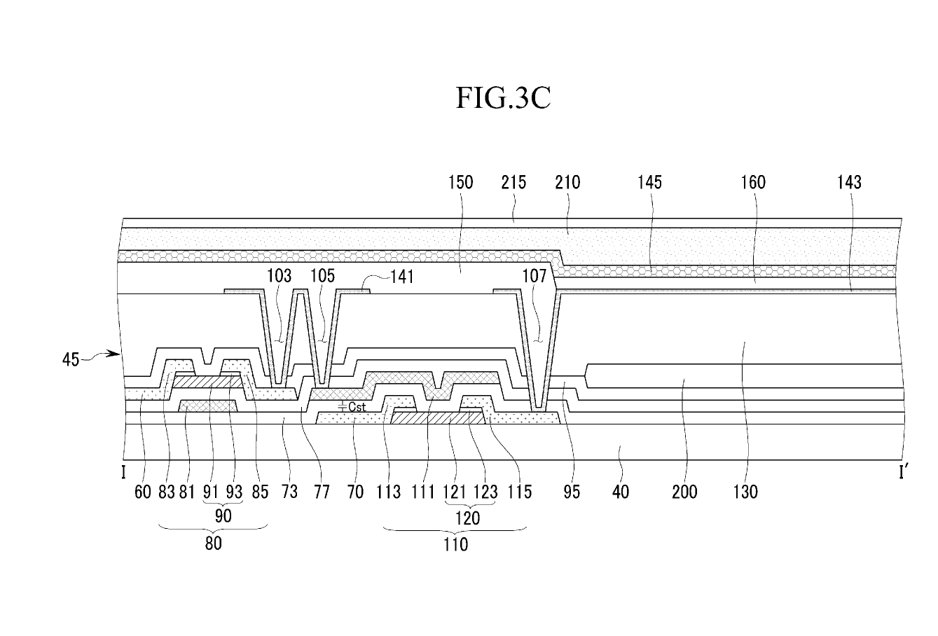

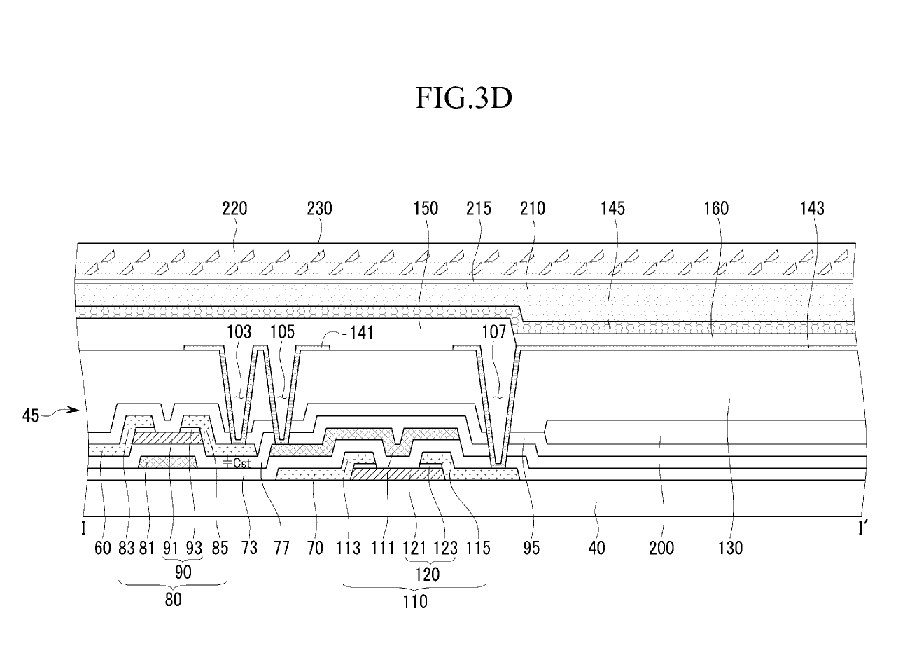

Next, an exemplary method of manufacturing an OLED device having such a structure above explained will be described with reference to FIGS. 3a to 3d.

FIGS. 3a to 3d are cross-sectional views illustrating steps of the method.

The method of manufacturing an OLED device in accordance with the present disclosure includes forming an organic light emitting pixel unit 45 on a transparent substrate 40, forming a first protective layer 210 on the organic light emitting pixel unit 45, forming a second protective layer 215 on the first protective layer 210, and forming a third protective layer having desiccant members 230 on in the second protective layer 215.

As shown in FIG. 3a, the structure where the organic light emitting pixel unit 45 is formed on a transparent substrate 40 is prepared. Specifically, the organic light emitting pixel unit 45 is completed when the second electrode 145 is formed on the organic light emitting layer 160. As the other steps of forming the organic light emitting pixel unit 45 is substantially the same as the prior methods, the detailed explanation for it is omitted here.

Next, the process of forming the first protective layer 210 on the organic light emitting pixel unit 45 will be described with reference to FIG. 3b below.

As shown in FIG. 3b, the first protective layer 210 is formed on the organic light emitting pixel unit 45. The first protective layer 210 is formed on the overall surface of the substrate 40 over the second electrode 145. The first protective layer 210, which is substantially free of any or of large sized desiccant particles, is formed on the upper surface of the second electrode 145 using a sealant made of any one selected from the group consisting of bisphenol type epoxy resin, epoxidized butadiene resin, fluorine type epoxy resin, and novolac type epoxy resin. Moreover, the first protective layer 210 is formed of a thickness greater than a step height of the second electrode 145 formed by the barrier layer 150 to reduce the step height, and the upper surface thereof is formed horizontally to prevent moisture or oxygen from penetrating between respective layers to be stacked or bonded later. At this time, the first protective layer 210 is formed on the upper surface of the second electrode 145 by a screen printing method or a dispensing method in view of the viscosity of the sealant.

Subsequently, as shown in FIG. 3c, the second protective layer 215 is formed on the first protective layer 210. The second protective layer 215 is formed of silicon nitride or silicon oxide by a CVD or a sputtering method. The second protective layer 215 is so dense as to guarantee blocking moisture. Additionally, as first protective layer 210 functions as a buffer when the second protective layer 215 is formed, the organic light emitting pixel unit 45 below does not be damaged by the CVD or sputtering process for forming the second protective layer 215. Also, the second protective layer 215, formed along the substantially planar first protective layer 210, has a good uniformity without pin holes.

Next, FIG. 3d is a cross-sectional view illustrating a step of forming a third protective layer on the third protective layer.

As shown in FIG. 3d, the third protective layer 220 is formed on second protective layer 215. The third protective layer 220 is formed of an epoxy-based sealant, like the first protective layer 210. Moreover, the third protective layer 220 comprises the large-sized desiccant particles 230 such as talc, silica gel, or other non-swelling desiccant particles usable to prevent the further penetration of moisture that managed to get in from the outside. The third protective layer 220 is formed such that the desiccant members 230 are distributed uniformly in the horizontal directions across the overall surface of the substrate 40. Furthermore, the third protective layer 220 is formed to have a planar top surface and/or a constant thickness such that a cover substrate 240 can be bonded thereto accurately later.

As shown in FIG. 2, the cover substrate 240 is bonded to the upper surface of the third protective layer 220. The cover substrate 240 is formed of an insulating material such as glass or plastic, like the substrate 40. The cover substrate 240 is bonded thereto by pressurizing the third protective layer 220 to finish the OLED device. After bonding the cover substrate 240 to the third protective layer 220, curing may be executed.

The process of forming the first protective layer 210, second protective layer 215, and the third protective layers 230 in accordance with the present disclosure is not limited to those described above with reference to FIGS. 3a to 3d. For example, the first protective layer 210 and the second protective layer 215 may be formed on the substrate 40 on which the organic light emitting pixel unit 45 is formed, and the third protective layer 220 may be formed on the cover substrate 240, and then two substrate 40 and 240 may be bonded to each other. In this case, the denser desiccant members 230 included in the third protective layer 220 are slowly settled down and move onto the surface of the cover substrate 240. With such desiccant members 230 moving onto the surface of the cover substrate 240, it is possible to prevent the situation where the larger desiccant particles in the third protective layer 220 damage the second electrode 145 by pressurizing of the first protective layer 210 while the third protective layer 220 is bonded to the first protective layer 210. After bonding two substrates 40 and, curing may be executed.

As described above, the OLED device in accordance with the present disclosure includes the first protective layer 210, the second protective layer 215 and the third protective layer 220.

As the first protective layer 210 functions as a buffer when the second protective layer 215 is formed, the organic light emitting pixel unit 45 underlying does not be damaged by the CVD or sputtering process for forming the second protective layer 215. Also, the second protective layer 215, formed along the substantially planar first protective layer 210, has a good uniformity without pin holes and is so dense as to guarantee blocking moisture. The third protective layer 220 comprises desiccant members 230 to remove moisture that manages to penetrate from the outside. The first protective layer 210 and the second protective layer 215 formed below the bottom of the third protective layer 220 acts to relieve the stress and strain of spot depressions caused by large ones of the desiccant members 230, thus preventing a possible failure of the OLE unit pixel 45 underlying.

Although the present disclosure has been described with reference to certain exemplary embodiments thereof, it will be understood by those skilled in the art that a variety of modifications and variations may be made to the present disclosure without departing from the spirit or scope of the present teachings.

What is claimed is:

1. An organic light emitting display device comprising:
a substrate;
an organic light emitting pixel unit formed on the substrate;
a first protective layer formed on the organic light emitting pixel unit;
a second protective layer formed on the first protective layer; and
a third protective layer formed on the second protective layer and including a desiccant member.

2. The organic light emitting display device of claim 1, further comprising a cover substrate compressively bonded to the third protective layer.

3. The organic light emitting display device of claim 1, wherein the first protective layer and the third protective layer are formed of a sealant material that inhibits passage of moisture therethrough.

4. The organic light emitting display device of claim 1, wherein the first protective layer and the third protective layer include an epoxy-base resin.

5. The organic light emitting display device of claim 1, wherein the second protective layer is formed of silicon oxide or silicon nitride.

6. The organic light emitting display device of claim 1, wherein the thickness of the first protective layer is larger than the maximum diameter of the desiccant member.

7. The organic light emitting display device of claim 1, wherein the thickness of the third protective layer is larger than the maximum diameter of the desiccant member.

8. The organic light emitting display device of claim 1, wherein the desiccant member is formed of talc or silica gel.

9. A method of manufacturing an organic light emitting display device comprising:
forming an organic light emitting pixel unit on a substrate;
forming a first protective layer on the organic light emitting pixel unit;
forming a second protective layer on the first protective layer; and
forming a third protective layer including a desiccant member on the second protective layer.

10. The method of claim 9, further comprising compressively bonding a cover substrate on the third protective layer.

11. The method of claim 9, wherein the first protective layer and the third protective layer is formed by a dispensing or screen printing method.

12. The method of claim 9, wherein the second protective layer is formed by CVD or sputtering method.

13. A method of manufacturing an organic light emitting display device comprising:
forming an organic light emitting pixel unit on a substrate;
forming a first protective layer on the organic light emitting pixel unit;
forming a second protective layer on the first protective layer;
forming a third protective layer including a desiccant member on a cover substrate; and
compressively bonding the substrate where the second protective layer is formed and the cover substrate where the third protective layer is formed on.

14. The method of claim 13, wherein the first protective layer and the third protective layer is formed by a dispensing or screen printing method.

15. The method of claim 13, wherein the second protective layer is formed by CVD or sputtering method.

16. An organic light emitting display device comprising:
a substrate;
an organic light emitting pixel unit formed on the substrate;
a first protective means for preventing the organic light emitting pixel unit from being physically damaged, wherein the first protective means is formed on the organic light emitting pixel unit and having a planar surface;
a second protective means for inhibiting passage of moisture and oxygen into the organic light emitting pixel unit, wherein the second protective means is formed on the first protective layer; and
a third protective means for inhibiting passage of moisture and oxygen into the organic 11 light emitting pixel unit, wherein the third protective means is formed on the second protective layer and includes a desiccant member.

17. The organic light emitting display device of claim 16, wherein the first protective means and the third protective means are formed of a sealant material.

18. The organic light emitting display device of claim 16, wherein the second protective means is formed of silicon oxide or silicon nitride.
